(19) United States
(12) Patent Application Publication
(10) Pub. No.: US 2010/0103584 A1
(43) Pub. Date: Apr. 29, 2010

(54) ELECTROSTATIC CHUCKING APPARATUS AND METHOD FOR MANUFACTURING THE SAME

(75) Inventor: Chang Kil NAM, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/581,147

(22) Filed: Oct. 18, 2009

(30) Foreign Application Priority Data
Oct. 28, 2008 (KR) 10-2008-0105949

(51) Int. Cl. H01L 21/683; B29C 65/48

(52) U.S. Cl. 361/234; 156/60

(57) ABSTRACT

An electrostatic chucking apparatus and a method for manufacturing the same is disclosed, which is capable of enabling the increase of lifetime of an electrostatic chuck and realizing a uniform temperature gradient in an entire substrate by preventing an insulating material from being etched, the electrostatic chucking apparatus comprising a base member; and an electrostatic chuck, loaded onto the base member, for chucking a substrate by an electrostatic force, wherein the electrostatic chuck comprises an insulating member formed on the base member and provided with a plurality of first insulating sheets of aluminum nitride; a heater for heating the substrate, the heater positioned among the plurality of first insulating sheets; a direct current electrode formed on at least one first insulating sheet provided above the heater among the plurality of first insulating sheets, the DC electrode electrically connected with a direct current power source; and an insulator etch stopping layer, formed of aluminum oxide on an entire surface of the insulating member, for preventing the insulating member from being etched.

### CROSS REFERENCE TO RELATED APPLICATIONS

This application claims the benefit of the Korean Patent Application No. P2008-0105949, filed on Oct. 28, 2008, which is hereby incorporated by reference as if fully set forth herein.

### BACKGROUND OF THE INVENTION

1. Field of the Invention

The present invention relates to an electrostatic chuck and a method for manufacturing the same, and more particularly, to an electrostatic chucking apparatus which is capable of enabling the increase of lifetime of an electrostatic chuck and realizing a uniform temperature gradient in an entire substrate by preventing an insulating material from being etched, and a method for manufacturing the same.

2. Discussion of the Related Art

Generally, a semiconductor device, a flat display device or a solar cell can be manufactured by oxidization, deposition and etching processes. These processes are carried out under such circumstance a substrate is fixedly loaded onto a chamber. For fixedly loading the substrate onto the chamber, a mechanical method or a vacuum chucking method has been used widely. In recent, an electrostatic chucking apparatus using an electrostatic force is more preferred.

The electrostatic chucking apparatus can be applied to entire steps for manufacturing the semiconductor device, for example, chemical vapor deposition, etching, sputtering, and ion implantation steps.

The electrostatic chucking apparatus chucks the substrate by Coulombic Force and Johnson-Rahbeck Force generated in an insulating layer positioned between an electrode and the substrate.

FIG. 1 illustrates a related art electrostatic chucking apparatus.

Referring to FIG. 1, the related art electrostatic chucking apparatus includes a base member 10 and an electrostatic chuck 20. The base member 10 is formed of an aluminum material, and the electrostatic chuck 20 is formed on the base member 10.

The base member 10 includes a passage 12 for heating a substrate (not shown), chucked to the electrostatic chuck 20, to a predetermined temperature. According as an externally-provided fluid 15 with a high temperature passes through the passage 12, the base member 10 transmits heat of the fluid 15 to the substrate, whereby the substrate electrostatic-chucked to the electrostatic chuck 20 is heated to the predetermined temperature.

The electrostatic chuck 20 includes an insulating member 22, and a direct current electrode (DC electrode) 24 formed inside the insulating member 22. As the electrostatic chuck 20 supplies a direct current power source to the DC electrode 24, an electrostatic force is generated in the insulating member 22, whereby the substrate (not shown) is electrostatic-chucked to the electrostatic chuck 20. Also, the electrostatic chuck 20 heats the substrate, which is electrostatic-chucked to the insulating member 22, to the predetermined temperature by using the heat of the fluid 15 transmitted from the base member 10.

However, the related art electrostatic chucking apparatus has the following disadvantages.

In the related art electrostatic chucking apparatus, the insulating member 22 may be etched by plasma (or etching gas) when cleaning a chamber by etching during or after the process, whereby a lifetime of the electrostatic chuck 20 may be shortened. Due to the short lifetime of the electrostatic chuck 20, the electrostatic chuck 20 has to be frequently replaced so that a yield is lowered and a maintenance cost is increased.

Since the base member 10 is different from the insulating member 22 of the electrostatic chuck 20 in thermal conductivity, and the passage 15 is distant from the substrate, it is difficult to realize a uniform temperature in the entire substrate. Furthermore, due to the imprecise temperature adjustment in the substrate, it is difficult to realize a uniform temperature gradient in the entire substrate.

### SUMMARY OF THE INVENTION

Accordingly, the present invention is directed to a an electrostatic chucking apparatus and a method for manufacturing the same that substantially obviates one or more problems due to limitations and disadvantages of the related art.

An object of the present invention is to provide an electrostatic chucking apparatus which is capable of enabling the increase of lifetime of an electrostatic chuck and realizing a uniform temperature gradient in an entire substrate by preventing an insulating material from being etched, and a method for manufacturing the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an electrostatic chucking apparatus comprises a base member; and an electrostatic chuck, loaded onto the base member, for chucking a substrate by an electrostatic force, wherein the electrostatic chuck comprises an insulating member formed on the base member and provided with a plurality of first insulating sheets of aluminum nitride; a heater for heating the substrate, the heater positioned among the plurality of first insulating sheets; a direct current electrode formed on at least one first insulating sheet provided above the heater among the plurality of first insulating sheets, the DC electrode electrically connected with a direct current power source: and an insulator etch stopping layer, formed of aluminum oxide on an entire surface of the insulating member, for preventing the insulating member from being etched.

At this time, the insulating member comprises a first insulating layer on the base member, the first insulating layer comprising at least one first insulating sheet being in contact: a second insulating layer on the first insulating layer under such circumstances that the heater is interposed therebetween, the second insulating layer comprising at least one first insulating sheet being in contact; and a third insulating layer on the second insulating layer under such circumstances that the DC electrode is interposed therebetween, the third insulating layer comprising at least one first insulating sheet being in contact.

Also, the insulator etch stopping layer comprises at least one second insulating sheet of aluminum oxide being in contact with the insulating member.

The heater comprises an internal heater heated by a first heater source and positioned at the central portion of the first insulating layer; and an external heater heated by a second heater source and positioned in the margin of the first insulating layer.

In addition, the electrostatic chucking apparatus further comprises a focus ring covering lateral sides of the electrostatic chuck, the focus ring formed on the base member.

The focus ring is formed of aluminum oxide.

In another aspect of the present invention, a method for manufacturing an electrostatic chucking apparatus comprises forming a first insulating layer of a first insulating material; providing a heater on the first insulating layer; forming a second insulating layer of the first insulating material on the first insulating layer under such circumstances that the heater is interposed between the first and second insulating layers; forming a direct current electrode on the second insulating layer, the DC electrode electrically connected with a direct current power source; forming a third insulating layer of the first insulating material on the DC electrode; forming an insulator etch stopping layer on the third insulating layer, wherein the insulator etch stopping layer is formed of a second insulating material which is different from the first insulating material; manufacturing an electrostatic chuck by adhering the first to third insulating layers including the heater and the DC electrode to the insulator etch stopping layer; and loading the electrostatic chuck onto the base member.

Each of the first to third insulating layers is formed of at least one first insulating sheet of the first insulating material.

The first insulating material is aluminum nitride.

The second insulating material is aluminum oxide.

The process of providing the heater on the first insulating layer comprises providing an internal heater heated by a first heater source at the central portion of the first insulating layer; and providing an external heater heated by a second heater source in the margin of the first insulating layer.

In addition, the method further comprises forming a focus ring covering lateral sides of the electrostatic chuck on the base member.

The focus ring is formed of aluminum oxide.

It is to be understood that both the foregoing general description and the following detailed description of the present invention arc exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a related art electrostatic chucking apparatus;

FIG. 2 illustrates an electrostatic chucking apparatus according to one embodiment of the present invention;

FIG. 3 illustrates an electrostatic chucking apparatus according to another embodiment of the present invention; and

FIGS. 4A to 41 are cross section views illustrating a method for manufacturing the electrostatic chucking apparatus according to the embodiment of the present invention.

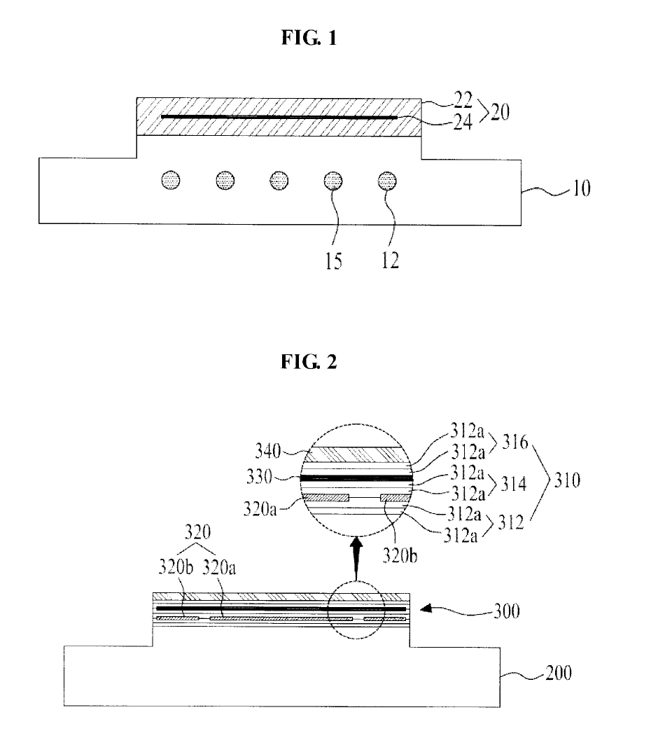

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an electrostatic chucking apparatus according to the present invention and a method for manufacturing the same will be described with reference to the accompanying drawings.

FIG. 2 illustrates an electrostatic chucking apparatus according to one embodiment of the present invention.

Referring to FIG. 2, the electrostatic chucking apparatus according to one embodiment of the present invention includes a base member 200 and an electrostatic chuck 300.

The base member 200 is made of a metal material. For example, the base member 200 may be made of aluminum (Al). The base member 200 may include an additional extending portion onto which the electrostatic chuck 300 is loaded.

The electrostatic chuck 300 includes an insulating member 310, a heater 320, a direct current electrode (DC electrode) 330, and an insulator etch stopping layer 340.

The insulating member 310 may include first, second, and third insulating layers 312, 314, and 316.

The first insulating layer 312 is deposited on the base member 200.

The second insulating layer 314 is deposited on the first insulating layer 312 under such circumstances that the heater 312 is interposed between the second insulating layer 314 and the first insulating layer 312.

The third insulating layer 316 is deposited on the second insulating layer 314 under such circumstances that the DC electrode 330 is interposed between the third insulating layer 316 and the second insulating layer 314.

Each of the first, second, and third insulating layers 312, 314, and 316 is formed of at least one first insulating sheet 312a which is made of aluminum nitride (AIN) having a thermal conductivity of 90 W/mk or above.

The heater 320 includes an internal heater 320a and an external heater 320b, wherein both the internal and external heaters 320a and 320b are positioned between the first and second insulating layers 312 and 314.

The internal heater 320a is formed in the central portion of the first insulating layer 312. The internal heater 320a is heated by an externally-provided first heater source, and then the internal heater 320a heats the central portion of the electrostatic chuck 300 to a predetermined temperature. In this case, the internal heater 320a may be formed to have a concentric-circle shape.

The external heater 320b is formed in the margin of the first insulating layer 312. The external heater 320b is heated by an externally-provided second heater source, and then the external heater 320b heats the margin of the electrostatic chuck 300 to a predetermined temperature. In this case, the external heater 320b may be formed to have a concentric-circle shape outside the external heater 320a.

In order to realize a simplified process for manufacturing the electrostatic chuck 300, each of the internal and external heaters 320a and 320b may be inserted into a heater insertion groove (not shown) which is formed at each corresponding portion on the surface of the first insulating layer 312.

The heater 320 including the separately-operable internal and external heaters 320a and 320b enables to realize a precise temperature control for the substrate, whereby a temperature can be selectively controlled on corresponding partial portions of the entire substrate, thereby realizing a uniform temperature gradient in the substrate.

The DC electrode 330 is formed in an electrode sheet positioned on the second insulating layer 314. The DC electrode 330 generates an electrostatic force by an externally-provided direct current, and the electrostatic force generated by the DC electrode 330 enables to chuck the substrate to the entire surface of the electrostatic chuck 300. In order to realize a simplified process for manufacturing the electrostatic chuck 300, the DC electrode 330 may be inserted into an electrode insertion groove (not shown) which is formed at a corresponding portion on the surface of the second insulating layer 314.

The DC electrode 330 and the insulating member 310 may be formed of materials which are similar in thermal expansions and qualities. For example, the DC electrode 330 may be made of titan (Ti), tungsten (W), or tantalum (Ta). The DC electrode 330 may be formed by any one method of pressurizing, screen printing, doctor blade, and tape casting.

The insulator etch stopping layer 340 is formed on an entire surface of the third insulating layer 316. Preferably, the insulator etch stopping layer 340 is made of a material which has a great thermal conductivity for efficiently transmitting the heat generated by the heater 320 to the substrate, and also has a high etch resistance by plasma. For this, the insulator etch stopping layer 340 is formed of at least one second insulating sheet of aluminum oxide (Al₂O₃) having a thermal conductivity of 18 W/mk or above. The insulator etch stopping layer 340 may be formed on the third insulating layer 316 under high temperature and high pressure. In this case, the insulator etch stopping layer 340 is thinner than the insulating member 310 so as to realize the smooth electrostatic chucking and the good thermal conductivity for the substrate. For example, the insulator etch stopping layer 340 has a thickness of about 7 mm preferably.

During or after a process for manufacturing a semiconductor device, the insulator etch stopping layer 340 can prevent the third insulating layer 316 from being etched by plasma (or etching gas) when cleaning a chamber by etching.

The aforementioned electrostatic chucking apparatus according to the present invention discloses that the insulator etch stopping layer 340 of aluminum oxide is formed on the insulating member 310 of aluminum nitride so as to prevent the insulating member 310 from being etched by plasma. Accordingly, the aforementioned electrostatic chucking apparatus according to the present invention enables to extend the lifetime of the electrostatic chuck 300, to reduce a maintenance cost owing to the extended period of replacing the electrostatic chuck 300, and to improve the yield in process for manufacturing the semiconductor device.

In the aforementioned electrostatic chucking apparatus according to the present invention, since the insulator etch stopping layer 340 is relatively thinner than the insulating member 310, the heat generated by the heater 320 is uniformly transmitted to the insulating member 310 having the high thermal conductivity, thereby enabling the uniform surface temperature of the electrostatic chuck 300. Also, the high thermal conductivity of the insulating member 310 enables to rapidly control heating and cooling of the electrostatic chuck 300, so that it is possible to improve the yield in process for manufacturing the semiconductor device.

FIG. 3 illustrates an electrostatic chucking apparatus according to another embodiment of the present invention, which includes an additionally-provided focus ring 400.

The focus ring 400, which covers lateral sides of an electrostatic chuck 300, is formed on a base member 200. In this case, the focus ring 400 may be formed of the same material as that of an insulator etch stopping layer 340.

The focus ring 400 protects lateral sides of the insulator etch stopping layer 340 as well as lateral sides of an insulating member 310 from plasma. Even though the insulator etch stopping layer 340 protects the insulating member 310 of the electrostatic chuck 300, the lateral sides of the insulating member 310 are exposed to plasma. In this respect, the focus ring 400 is provided to protect the lateral sides of the electrostatic chuck 300 from plasma.

Also, the focus ring 400 is provided to concentrate plasma on a predetermined portion for loading the substrate during the process for manufacturing the semiconductor device using plasma.

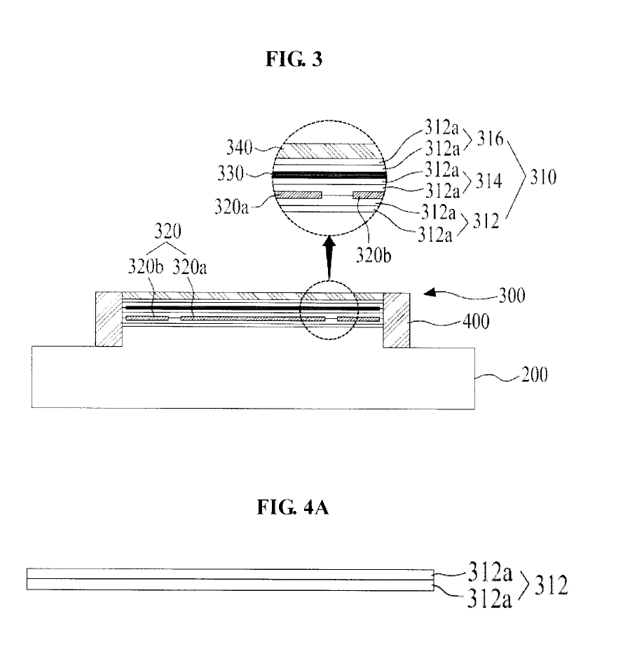

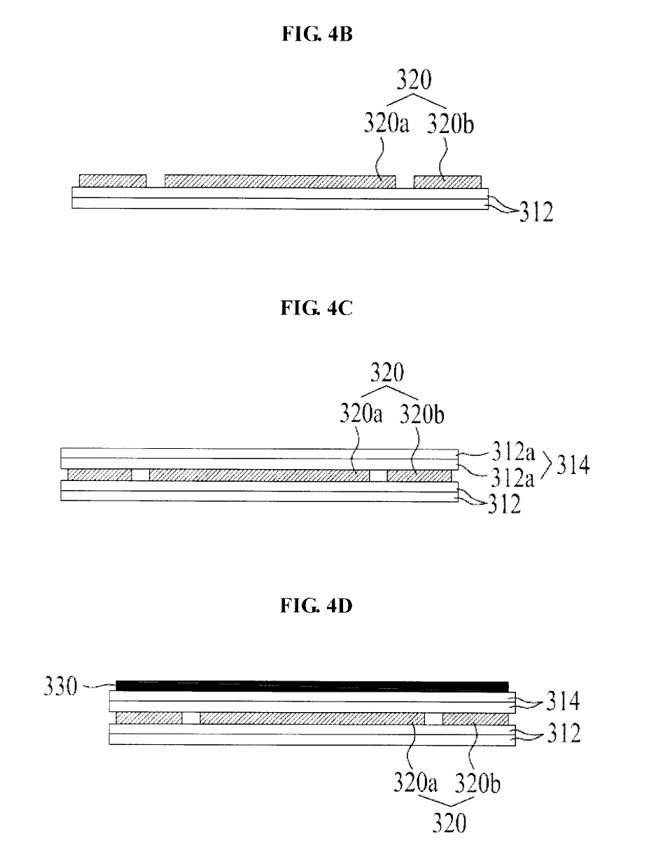

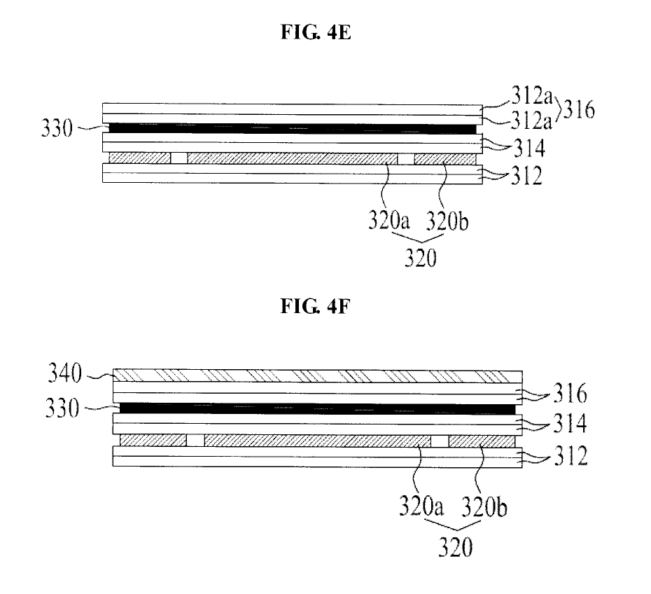

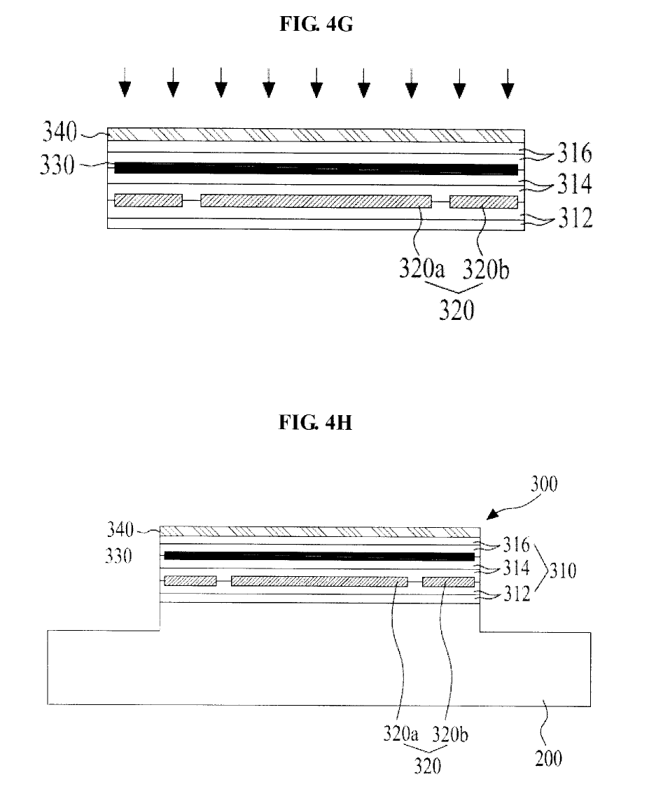

FIGS. 4A to 41 are cross section views illustrating a method for manufacturing the electrostatic chucking apparatus according to the embodiment of the present invention.

A method for manufacturing the electrostatic chucking apparatus according to embodiment of the present invention will be explained with reference to FIGS. 4A to 41.

First, as shown in FIG. 4A, the first insulating layer 312 is formed of at least one first insulating sheet 312a of aluminum nitride.

As shown in FIG. 4B, the heater 320 including the internal and external heaters 320a and 320b is deposited on the first insulating layer 312.

At this time, the heater 320 includes the internal heater 320a and the external heater 320b. The internal heater 320a is formed at the central portion of the first insulating layer 312, and the internal heater 320a is heated by the externally-provided first heater source. Also, the external heater 320b is formed in the margin of the first insulating layer 312, and the external heater 320b is heated by the second heater source. In order to simplify the process for manufacturing the electrostatic chuck 300, each of the internal and external heaters 320a and 320b may be inserted into the heater insertion groove (not shown) which is provided at each corresponding portion on the surface of the first insulating layer 312.

As shown in FIG. 4C, the second insulating layer 314 is formed on the heater 320, wherein the second insulating layer 314 is formed of at least one first insulating sheet 312a.

As shown in FIG. 4D, the DC electrode 330 is formed on the second insulating layer 314. For simplifying the process for manufacturing the electrostatic chuck 300, the DC electrode 330 may be inserted into the electrode insertion groove (not shown) which is formed at the corresponding portion on the surface of the second insulating layer 314.

The DC electrode 330 may be formed on an additional electrode sheet positioned above the second insulating layer 314.

As shown in FIG. 4E, the third insulating layer 316 is formed on the second insulating layer 314 under such circumstances that the DC electrode 330 is interposed between the third insulating layer 316 and the second insulating layer 314, wherein the third insulating layer 316 is formed of at least one first insulating sheet 312a.

As shown in FIG. 4F, the insulator etch stopping layer 340 is formed on the third insulating layer 316, wherein the insulator etch stopping layer 340 is formed of at least one second insulating sheet of aluminum oxide.

As shown in FIG. 4G, the insulator etch stopping layer 340 and the first to third insulating layers 312, 314, and 316 including the heater 320 and the DC electrode 330 are formed under the high temperature and high pressure, thereby manufacturing the electrostatic chuck 300.

As shown in FIG. 4H, the manufactured electrostatic chuck 300 is loaded onto the base member 200, thereby manufacturing the electrostatic chucking apparatus.

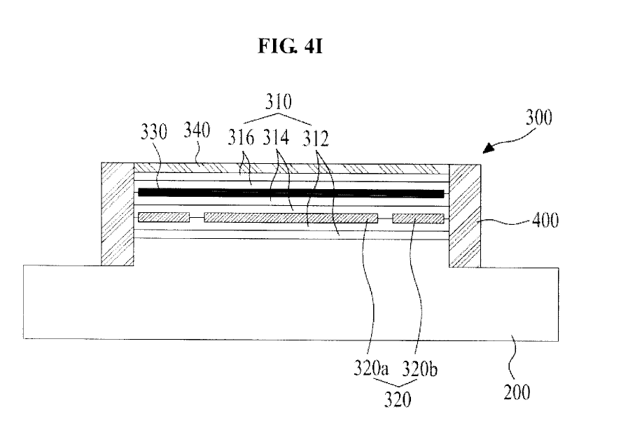

In the method for manufacturing the electrostatic chucking apparatus according to the embodiment of the present invention, as shown in FIG. 41, the focus ring 400 covering the lateral sides of the electrostatic chuck 300 is formed on the base member 200. At this time, the focus ring 400 may be made of the same material as that of the insulator etch stopping layer 340.

Accordingly, the electrostatic chucking apparatus according to the present invention and the method for manufacturing the same have the following advantages.

As the insulator etch stopping layer 340 of aluminum oxide is formed on the insulating member 310 of aluminum nitride, it is possible to prevent the insulating member 310 from being etched by plasma. Thus, the increased lifetime of the electrostatic chuck 300 enables to extend the period of replacing the electrostatic chuck 300, to reduce the maintenance cost, and to improve the yield in the process for manufacturing the semiconductor device.

Since the insulator etch stopping layer 340 is relatively thinner than the insulating member 310, the heat generated by the heater 320 is uniformly transmitted to the insulating member 310 having the high thermal conductivity, thereby enabling the uniform surface temperature of the electrostatic chuck 300. Also, the high thermal conductivity of the insulating member 310 enables to rapidly control heating and cooling of the electrostatic chuck 300, so that it is possible to improve the yield in process for manufacturing the semiconductor device.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An electrostatic chucking apparatus comprising a base member; and an electrostatic chuck, loaded onto the base member, for chucking a substrate by an electrostatic force,
wherein the electrostatic chuck comprises:
an insulating member formed on the base member and provided with a plurality of first insulating sheets of aluminum nitride;
a heater for heating the substrate, the heater positioned among the plurality of first insulating sheets;
a direct current electrode formed on at least one first insulating sheet provided above the heater among the plurality of first insulating sheets, the DC electrode electrically connected with a direct current power source; and
an insulator etch stopping layer, formed of aluminum oxide on an entire surface of the insulating member, for preventing the insulating member from being etched.

2. The electrostatic chucking apparatus of claim 1, wherein the insulating member comprises:
a first insulating layer on the base member, the first insulating layer comprising at least one first insulating sheet being in contact;
a second insulating layer on the first insulating layer under such circumstances that the heater is interposed therebetween, the second insulating layer comprising at least one first insulating sheet being in contact; and
a third insulating layer on the second insulating layer under such circumstances that the DC electrode is interposed therebetween, the third insulating layer comprising at least one first insulating sheet being in contact.

3. The electrostatic chucking apparatus of claim 1, wherein the insulator etch stopping layer comprises at least one second insulating sheet of aluminum oxide being in contact with the insulating member.

4. The electrostatic chucking apparatus of claim 2, wherein the heater comprises:
an internal heater heated by a first heater source and positioned at the central portion of the first insulating layer; and
an external heater heated by a second heater source and positioned in the margin of the first insulating layer.

5. The electrostatic chucking apparatus of claim 1, further comprising a focus ring covering lateral sides of the electrostatic chuck, the focus ring formed on the base member.

6. The electrostatic chucking apparatus of claim 5, wherein the focus ring is formed of aluminum oxide.

7. A method for manufacturing an electrostatic chucking apparatus comprising:
forming a first insulating layer of a first insulating material;
providing a heater on the first insulating layer;
forming a second insulating layer of the first insulating material on the first insulating layer under such circumstances that the heater is interposed between the first and second insulating layers;
forming a direct current electrode on the second insulating layer, the DC electrode electrically connected with a direct current power source;
forming a third insulating layer of the first insulating material on the DC electrode;
forming an insulator etch stopping layer on the third insulating layer, wherein the insulator etch stopping layer is formed of a second insulating material which is different from the first insulating material;
manufacturing an electrostatic chuck by adhering the first to third insulating layers including the heater and the DC electrode to the insulator etch stopping layer; and
loading the electrostatic chuck onto the base member.

8. The method of claim 7, wherein each of the first to third insulating layers is formed of at least one first insulating sheet of the first insulating material.

9. The method of claim 7, wherein the first insulating material is aluminum nitride.

10. The method of claim 7, wherein the second insulating material is aluminum oxide.

11. The method of claim 7, wherein the process of providing the heater on the first insulating layer comprises:
providing an internal heater heated by a first heater source at the central portion of the first insulating layer; and
providing an external heater heated by a second heater source in the margin of the first insulating layer.

12. The method of claim 7, further comprising forming a focus ring covering lateral sides of the electrostatic chuck on the base member.

13. The method of claim 12, wherein the focus ring is formed of aluminum oxide.
